(19) United States
(12) Patent Application Publication
(10) Pub. No.: US 2017/0001857 A1
(43) Pub. Date: Jan. 5, 2017

(54) SENSOR ELEMENT AND METHOD OF MANUFACTURING THE SAME

(71) Applicant: SAMSUNG ELECTRO-MECHANICS CO., LTD., Suwon-si (KR)

(72) Inventors: Dae Hun JEONG, Suwon-si (KR); Chang Hyun LIM, Suwon-si (KR); Tae Hun LEE, Suwon-si (KR)

(73) Assignee: SAMSUNG ELECTRO-MECHANICS CO., LTD., Suwon-si (KR)

(21) Appl. No.: 15/059,803

(22) Filed: Mar. 3, 2016

(30) Foreign Application Priority Data
Jul. 1, 2015 (KR) 10-2015-0094036

(51) Int. Cl. B81B 3/00; B81C 1/00

(52) U.S. Cl. CPC B81B 3/0072; B81C 1/00404; B81B 2201/0264; B81B 2203/0118; B81B 2203/0109; B81B 2203/033; B81C 2201/0132

(57) ABSTRACT

Provided are sensor elements and a method of manufacturing the same. The sensor element includes a die, an active part including a frame surrounded by the die, a first trench disposed between the die and the active part, and a bridge connecting the die and the frame and a second trench being formed in the bridge, whereby electrical connection from the active part to an electrode pad may be secured and transfer of external stress to the active part may be significantly reduced through the second trench.

### CROSS-REFERENCE TO RELATED APPLICATION

This application claims the priority and benefit under 35 USC §119(a) of Korean Patent Application No. 10-2015-0094036, filed on Jul. 1, 2015 with the Korean Intellectual Property Office, the entire disclosure of which is incorporated herein by reference for all purposes.

### BACKGROUND

1. Field

The following description relates to a sensor element and a method of manufacturing the same.

2. Description of Related Art

Performance of semiconductor elements such as, for example, pressure sensors, acceleration sensors, inertial sensors, and flow sensors is often limited by external force when a package is deformed and installed.

As a pressure sensor, a piezoresistive type pressure sensor, which senses stress generated when a membrane covering a cavity of a die is deformed by pressure has been used. In order to implement a high-precision pressure sensor, the membrane should be deformed only by pressure, and should not be deformed by other factors. One of the main factors reducing precision of a pressure sensor is stress generated when deformation generated at an outer portion such as, for example. a package is transferred to the membrane through the die.

Therefore, various methods for significantly reducing external stress transferred to an active part such as, for example, a membrane have been attempted in order to improve sensor precision.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a sensor element capable of blocking external stress by a simple manufacturing process, and a method of manufacturing the same.

In another general aspect, there is provided a sensor element including a die, an active part including a frame surrounded by the die, a first trench disposed between the die and the active part, and a bridge connecting the die and the frame and a second trench being formed in the bridge.

An end of the die may be fixed to a substrate, and a space may be formed between a lower end of the frame and the substrate.

The active part may include a cavity formed in an upper surface of the frame, a membrane formed on the upper surface of the frame to cover the cavity, and at least one sensor disposed on the membrane.

The active part may include a cavity formed in the frame, a mass body disposed in the cavity and surrounded by the frame, beams connecting the mass body and the frame to each other and elastically supporting the mass body, and sensing parts disposed on the beams and being configured to sense a deformation of the beams.

The second trench may be formed in a thickness direction of the bridge.

The end of the die may be fixed to the substrate by an adhesion layer.

The sensor may be disposed at a position where the membrane and the frame connect to each other.

The second trench may be shaped as a groove with a depth of the groove being lesser than a thickness of the bridge.

An end of the die may protrude below the lower end of the frame.

According to another aspect there is provided, a sensor element including a die, an active part including a frame surrounded by the die with a first trench disposed between the frame and the die, and at least one elastic support part connecting the die and the frame, the elastic support part including an elastic part, and having a second trench formed in the elastic part.

An end of the die may be fixed to a substrate, and a space may be formed between a lower end of the frame and the substrate.

The active part may include a cavity formed in an upper surface of the frame, a membrane formed on the upper surface of the frame to cover the cavity, and at least one sensor disposed on the membrane.

The active part may include a cavity formed in the frame, a mass body disposed in the cavity and surrounded by the frame, beams connecting the mass body and the frame to each other and elastically supporting the mass body, and sensing parts disposed on the beams and being configured to sense deformation of the beams.

The elastic support part may include the elastic part disposed parallel to an inner surface of the die or an outer surface of the frame and being positioned in the first trench, and a first and a second connection part extending from two ends of the elastic part to connect the die and the frame, and the first connection part extending toward the inner surface of the die and the second connection part extending toward outer surface of the frame.

The second trench may be formed in a thickness direction in the first or the second connection part.

The first and the second connection part may extend from the elastic part in a direction approximately perpendicular to a length direction of the elastic.

According to another general aspect, there is provided a method of manufacturing a sensor element including forming an etch mask on a die, forming slit patterns for forming first and second trenches on the etch mask, and anisotropically etching the die.

A width of the slit pattern for forming the second trench may be narrower than a width of the slit pattern for forming the first trench.

The first and second trenches may be formed at the same time through deep reactive ion etching (DRIE) during the anisotropical etching.

Other features and aspects will be apparent from the following detailed description, the drawings, and the claims.

### BRIEF DESCRIPTION OF DRAWINGS

FIG. 1 is a diagram illustrating an example of a sensor element.

FIG. 2 is a diagram illustrating an example of an enlarged view of part A of FIG. 1.

FIG. 3 is a diagram illustrating an example of a cross-sectional view of the sensor element taken along line B-B of FIG. 1.

FIG. 4 is a diagram illustrating an example of a cross-sectional view of a deformed state of the sensor element disclosure taken along line B-B of FIG. 1.

FIG. 5 is a diagram illustrating an example of a sensor element.

FIG. 6 is a diagram illustrating an example of an enlarged view of part C of FIG. 5.

FIG. 7 is a diagram illustrating an example of a sensor element.

FIG. 8 is a diagram illustrating an example of a sensor element.

FIGS. 9A through 9D are diagrams illustrating examples of a method of manufacturing a sensor element.

FIGS. 10A and 10B are diagrams illustrating examples of a microloading effect.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless indicated otherwise, it will be understood that when a first element, such as a layer, region or wafer (substrate), is referred to as being “on,” “connected to,” or “coupled to” a second element, it can cover both a case where the first element directly contacts the second element, and a case where one or more other elements are disposed between the first element and the second element. When an element is referred to as being “directly on,” “directly connected to,” or “directly coupled to” another element, there may be no elements or layers between the two elements. As used herein, the term “and/or” includes any and all combinations of one or more of the associated listed items.

The terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the example embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

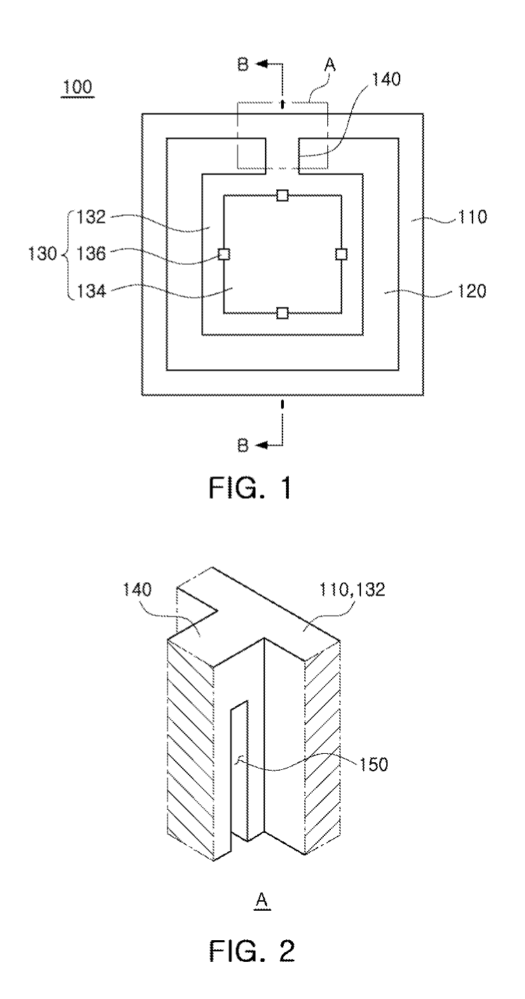

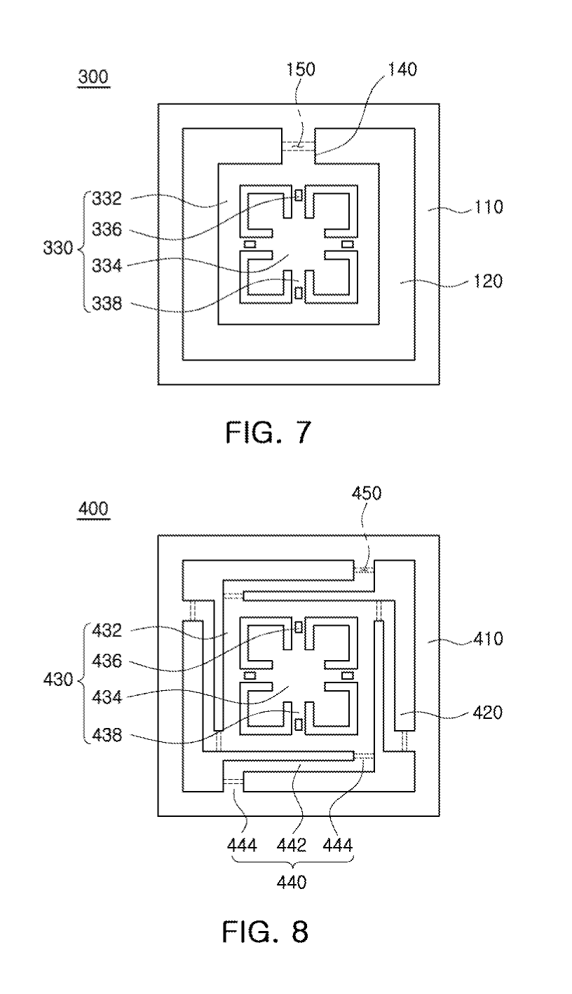

For ease of explanation, an example in which a sensor element is applied to a pressure sensor will be described with reference to FIGS. 1 through 6. However, the present disclosure is not limited to a pressure sensor, and is equally applicable to many other semiconductor elements. For example, the sensor element according to the present disclosure may be applied to an acceleration sensor, which is illustrated in FIGS. 7 and 8.

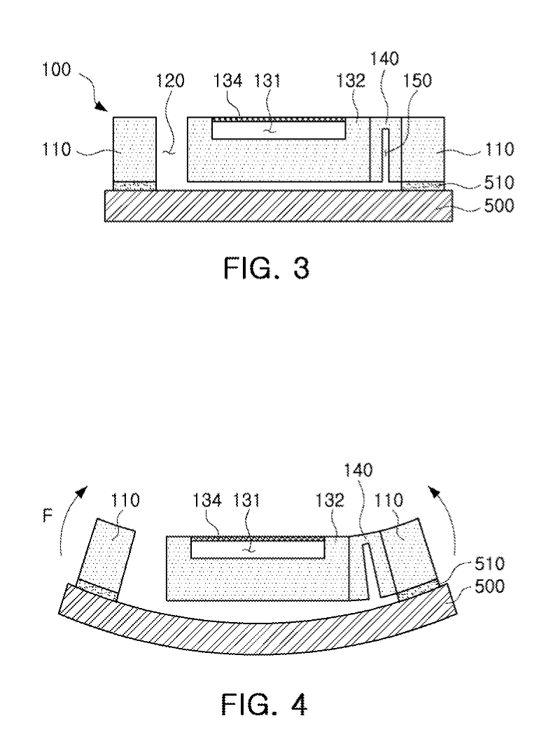

FIG. 1 is a diagram illustrating an example of a sensor element. FIG. 2 is a diagram illustrating an example of an enlarged view of part A of FIG. 1. FIG. 3 is a diagram illustrating an example of the sensor element taken along line B-B of FIG. 1. FIG. 4 is a diagram illustrating an example of a deformed state of the sensor element taken along line B-B of FIG. 1.

As illustrated in FIGS. 1 through 4, a sensor element 100 may include a die 110, an active part 130 including a frame 132 surrounded by the die. A first trench 120 is interposed between the die 110 and the active part 130. At least one bridge 140 connecting the die 110 and the frame 132 to each other and having a second trench 150 formed therein.

The die 110, which is a semiconductor substrate, may be a general silicon substrate. In an example, the die 110 may be formed of single crystal silicon or silicon-on-insulator (SOI) technology. In addition, the die 110 may have a form in which one or more silicon layers are stacked.

As described below, the die 110 may be etched to form the first trench 120, thereby forming the frame 132 and the bridge 140 connecting the frame 132 and the die 110 to each other.

The die 110 may be disposed in the vicinity of the frame 132 to surround the frame 132 while having a gap between the die 110 and the frame 132. The frame 132 may be accommodated in an internal space of the die. The first trench 120 may be provided between the die 110 and the frame 132 so that the die 110 and the frame 132 are spaced apart from each other. In an example, the first trench may have a through-hole shape.

For example, as illustrated in FIG. 1, when the frame 132 has a shape with an approximately quadrangular cross section, the die 110 may also have a shape with an approximately quadrangular cross section of which an inner portion is empty.

Therefore, outer surfaces of the frame 132 and inner surfaces of the die 110 may correspond to and face each other. The frame 132 and the die 110, however, are not limited to having the above-mentioned shape and disposition. Other arrangements and shapes of the frame 132 and the die 110 are considered to be well within the scope of the present disclosure.

A lower portion of the die 110 may extend to a position lower than a lower portion of the frame 132. A lower end of the die protruding to the position lower than the lower portion of the frame may be fixed to a substrate 500. Therefore, a space may be formed between a lower end of the frame and the substrate 500.

In another example, the die 110 and the frame 132 may have the same thickness, and an adhesion layer 510 may be formed at a thickness beneath only the lower end of the die 110 to bond the die 110 to the substrate 500. A space may be formed between a lower end of the frame 132 and the substrate 500.

In an example, a material of the substrate 500 may be glass, but is not limited thereto. Other material of the substrate 500 are considered to be well within the scope of the present disclosure. For example, substrates 500 made of silicon may be used.

The die 110 may be bonded and fixed to the substrate 500, and the active part 130 may not be fixed to the substrate, but may be elastically supported through the bridge 140, whose one end is fixed to the die.

A cavity 131 may be formed in an upper surface of the frame 132.

For example, when the sensor element 100 is applied to a pressure sensor, the active part 130 may include a membrane 134 thinly formed on the upper surface of the frame 132 and at least one sensing part 136 disposed on an upper surface of the membrane.

In an example, the membrane 134 may have a thin film form, and may be coupled to the frame 132 to cover and seal the cavity 131 on the upper surface of the frame 132. Therefore, the cavity of the frame may become a space sealed by the membrane.

In an example, the membrane 134 may be formed of a polysilicon layer or a silicon oxide layer. Other material of the membrane 134 are considered to be well within the scope of the present disclosure. For example, the membrane 134 may be formed by stacking the polysilicon layer and the silicon oxide layer.

The sensing part 136 may include a plurality of piezo-resistors (or piezoresistive elements). The sensing part 136 may be formed on the upper surface of the membrane. The sensing part 136 may be disposed on a portion at which the membrane 134 and the frame 132 are connected to each other.

When the membrane 134 is deformed by external force, stress of the membrane 134 may be concentrated on the sensing part 136, and thus a resistance value of the piezo-resistor is changed, and pressure may be sensed and measured through the change in the resistance value.

The change in pressure may be determined by measuring the difference in the output voltage of the sensing part 136. For example, when deformation is not generated in membrane 134, an output voltage of the sensing part 136 may be 0 V. When the deformation is generated in the membrane 134 due to a change in the surrounding pressure, a resistance value of at least one of the piezoelectric resistors may be changed, and thus a value different than 0 V is output as an output voltage of the sensing part 136.

The bridge 140 may have one end connected to the die 110 and the other end connected to the frame 132 to connect the die 110 and the frame 132 to each other.

In an example, the bridge 140 in the sensor element 100 may be formed as a cantilever spring to somewhat elastically support the frame 132.

Therefore, when stress is applied to the sensor element 100 by external force, the bridge 140 may alleviate the stress through bending, thereby blocking, to some degree, the external force from being directly introduced from the die 110 to the frame 132.

In addition, in the sensor element 100, the bridge 140 may have the second trench 150 formed at one side thereof to more elastically support the frame 132.

The second trench 150 may be formed together with the bridge 140 by etching the die 110. The second trench 150 may be formed in a thickness direction of the bridge. The second trench 150 may be shaped like a slit, which has a closed upper portion for connection and an open lower portion, i.e., the second trench may have a groove shape with a depth.

The second trench 150 may be formed in a lower portion of the bridge 140, and thus the sensing part 136 of the active part 130 and an electrode pad (not illustrated) placed on the die 110 may be electrically connected to each other through the bridge 140.

The second trench 150 is not limited to having the above-mentioned shape and disposition, and other shape and disposition are considered to be well within the scope of the present disclosure.

The second trench 150 may be formed in the bridge 140 to reduce a cross-sectional area of the bridge 140 connecting the active part 130 and the die 110 to each other, thereby more effectively blocking impact or external force from being transferred from the die 110 to the frame 132 of the active part 130.

For example, when deformation such as, for example, warpage is generated in the substrate 500, the die 110 fixed to the substrate 500 may also be deformed together with the substrate 500. In this case, the active part 130 may also be affected by this deformation, and thus a resistance value of the sensing part 136 of the active part is changed, whereby an output voltage of the pressure sensor may also be changed.

When the output voltage of the sensing part 136 is changed due to the deformation as described above, it may be difficult to distinguish a case in which the output voltage of the sensing part 136 is changed due to the deformation from a case in which the output voltage of the sensing part 136 is changed due to a change in actual pressure. When the deformation and the change in pressure are simultaneously generated, since the output voltage depending on the change in pressure is not singularly output, but rather is output together with the output voltage depending on the deformation, a precision of measurement of the change in pressure may be reduced.

Therefore, in the sensor element 100, the second trench 150 may block the impact or the external force from being transferred from the die 110 to the active part 130.

As illustrated in FIG. 4, a force F having a magnitude may act from one side or both sides of the die 110. This force may cause deformation of the active part 130 together with the substrate.

However, in the sensor element 100, the second trench 150 may be formed in the bridge 140, and when the impact or the external force is applied to the sensor element 100, the bridge 140 may prevent deformation of the active part 130, while itself being deformed.

As illustrated in FIG. 4, when the impact or the external force is applied to the sensor element 100, the second trench 150 may become wide or narrow to block the transfer of the impact or the external force so that the active part 130 is not deformed due to external stress.

Therefore, reliability of an operation of the sensor element may be maintained even in a case in which the impact or the external force is applied to the sensor element.

Although not illustrated, wiring patterns may be formed on surfaces of the die 110, the frame 132, and the bridge 140 connecting the die 110 and the frame 132 to each other. The wiring patterns may electrically connect the sensing parts 136 to electrical pads or the substrate 500.

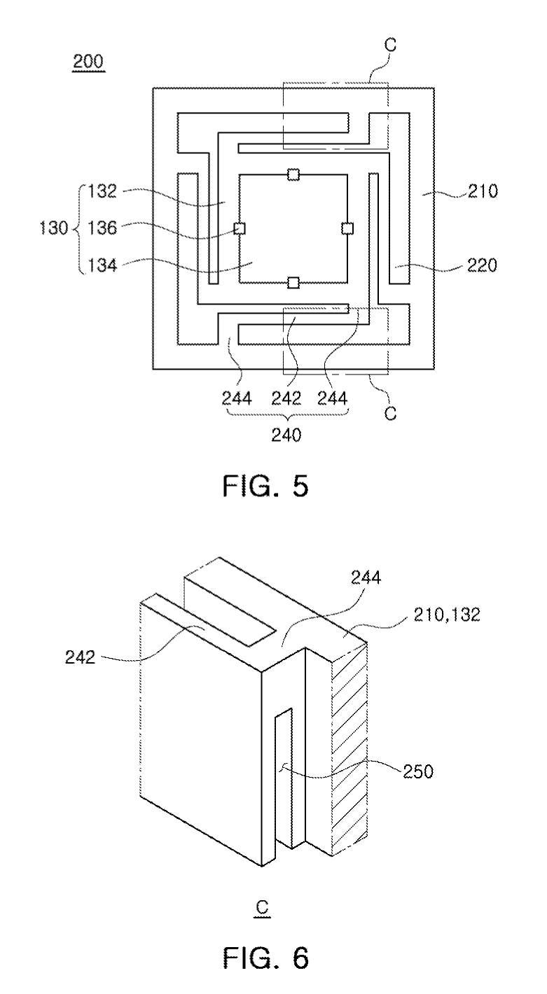

FIG. 5 is a diagram illustrating an example of a sensor element and FIG. 6 is a diagram illustrating an example of an enlarged view of part C of FIG. 5. Some of the components shown in FIGS. 5-6 have been described with reference to FIGS. 1-4. The above description of FIGS. 1-4, is also applicable to FIGS. 5-6, and is incorporated herein by reference. Thus, the above description may not be repeated here.

As illustrated in FIGS. 5 and 6, a sensor element 200 may include a die 210, an active part 130 including a frame 132 surrounded by the die with a first trench 220 interposed therebetween. At least an elastic support part 240 connects the die 210 and the frame 132 to each other, including an elastic part 242, and having a second trench 250 formed therein.

Similar to the die 110 described above, the die 210, which is a semiconductor substrate, may be a general silicon substrate.

As described below, the die 210 may be etched to form the first trench 220, thereby forming the frame 132 and the elastic support part 240 connecting the frame 132 and the die 210 to each other.

The die 210 may be disposed in the vicinity of the frame 132 to surround the frame 132 while having a gap between the die 110 and the frame 132. The frame 132 may be accommodated in an internal space of the die 210. The first trench 220 may be provided between the die 210 and the frame 132 so that the die 110 and the frame 132 are spaced apart from each other. In an example, the first trench may have a through-hole shape.

For example, as illustrated in FIG. 5, when the frame 132 has a shape with an approximately quadrangular cross section, the die 210 may also have a shape with an approximately quadrangular cross section of which an inner portion is empty.

Therefore, outer surfaces of the frame 132 and inner surfaces of the die 210 may be disposed to correspond to and face each other. The frame 132 and the die 210, however, are not limited to having the above-mentioned shape and disposition. Other arrangements and shapes of the frame 132 and the die 110 are considered to be well within the scope of the present disclosure.

A lower portion of the die 210 may extend to a position lower than a lower portion of the frame 132. A lower end of the die protruding to the position lower than the lower portion of the frame may be bonded to a substrate 500 (see FIG. 3). Therefore, a space may be formed between a lower end of the frame and the substrate 500.

In another example, the die 210 and the frame 132 may have the same thickness, and an adhesion layer 510 (see FIG. 3) may be formed at a thickness beneath only the lower end of the die 210 to bond the die 210 to the substrate 500. A space may be formed between a lower end of the frame 132 and the substrate 500.

The die 210 may be bonded and fixed to the substrate 500, and the active part 130 may not be fixed to the substrate, but may be elastically supported through the elastic support part 240, whose one end is fixed to the die.

A cavity 131, similar to what is shown in FIG. 3, may be formed in an upper surface of the frame 132.

For example, when the sensor element is applied to a pressure sensor, the active part 130 may include a membrane 134 thinly formed on the upper surface of the frame 132 and at least one sensing part 136 disposed on an upper surface of the membrane.

In an example, the membrane 134 may have a thin film form, and may be coupled to the frame 132 to cover and seal the cavity 131 on the upper surface of the frame 132. Therefore, the cavity of the frame may become a space sealed by the membrane.

The sensing part 136 may include a plurality of piezo-resistors (or piezoresistive elements). The sensing part 136 may be formed on the upper surface of the membrane. The sensing part 136 may be disposed on a portion at which the membrane 134 and the frame 132 are connected to each other.

When the membrane 134 is deformed by external force, stress of the membrane 134 may be concentrated on the sensing part 136, and thus a resistance value of the piezo-resistor may be changed, and pressure may be sensed and measured through the change in the resistance value. As described above, the change in pressure may be determined by measuring the difference in the output voltage of the sensing part 136.

The elastic support part 240 may have one end connected to the die 210 and the other end connected to the frame 132 to connect the die 210 and the frame 132 to each other.

In an example, the elastic support part 240 in the sensor element 200 may include the elastic part 242, which extends in parallel to an inner surface of the die 210 or an outer surface of the frame 132. The elastic support part 240 is positioned in the first trench 220, and a pair of connection parts 244 extend from both ends of the elastic part 242 toward the inner surface of the die and the outer surface of the frame. The pair of connection parts 244 are each connected to the die and the frame, respectively.

In an example, the elastic part 242 of the elastic support part 240 may have a leaf spring shape to elastically support the frame 132.

The connection parts 244 may be extended from both ends of the elastic part 242 toward the inner surface of the die 210 and the outer surface of the frame 132 in a direction approximately perpendicular to a length direction of the elastic part, and may have distal ends each connected to the die and frame.

Therefore, the die 210 and the frame 132 may be connected to either ends of the elastic part 242, respectively. Thus, the elastic support part 240 may provide a buffering effect between the die 210 and the frame 132 through elastic force of the elastic part 242.

As illustrated in FIG. 5, four elastic support parts 240 may be disposed on four side surfaces of the frame 132. Therefore, the elastic support parts 240 may elastically support movement of the frame in four directions of the die 210. However, the number or position of the elastic support parts 240 are not limited thereto. Other arrangements and number of the frame elastic support parts 240 are considered to be well within the scope of the present disclosure. For example, a number of elastic support parts may be disposed in various forms depending on a shape of the frame 132, die 210, or the elastic support part 240.

Therefore, when impact or external force is applied to the sensor element 200, the elastic support part 240 may alleviate the impact through the elastic force to reduce direct introduction of the impact from the die 210 to the frame 132.

In addition, in the sensor element 200, at least one connection part 244 may have the second trench 250 formed at one side thereof to more elastically support the frame 132.

The second trench 250 may be formed together with the elastic support part 240 by etching the die 210. As shown in FIG. 6, the second trench 250 may be formed in a thickness direction of the connection part 244. The second trench 250 may be shaped like a slit, which has a closed upper portion for connection and an open lower portion, i.e., the second trench may have a groove shape with a depth.

The second trench 250 may be formed in a lower portion of the elastic support part 240, and thus the sensing part 136 of the active part 130 and an electrode pad (not illustrated) placed on the die 210 may be electrically connected to each other through the elastic support part 240.

However, the second trench 250 is not limited to having the above-mentioned shape and disposition, and may also be formed in, for example, the elastic part 242.

As described above, the second trench 250 may be formed in the connection part 244 of the elastic support part 240, thereby more effectively blocking the impact or the external force from being transferred from the die 210 to the frame 132 of the active part 130.

In an example, the active part 130 may be three-dimensionally and elastically moved by the elastic support part 240 having the configuration described above.

Therefore, in the sensor element 200, the second trench 250 may be formed in the elastic support part 240 to block the impact or the external force from being transferred from the die 210 to the active part 130, thereby increasing a precision of measurement.

When the impact or the external force is applied to the sensor element 200, the second trench 250 may become wide or narrow to block the transfer of the impact or the external force so that the active part 130 is not deformed due to external stress. Therefore, reliability of an operation of the sensor element may be maintained even when the impact or the external force is applied to the sensor element.

Although not illustrated, wiring patterns may be formed on surfaces of the die 210, the frame 132, and the elastic support part 240 connecting the die 210 and the frame 132 to each other. The wiring patterns may electrically connect the sensing parts 136 to electrical pads or the substrate 500.

FIG. 7 is a diagram illustrating an example of a sensor element. Some of the components shown in FIG. 7 have been described with reference to FIGS. 1-6. For example, components of a sensor element in FIG. 7, except for an active part, may be the same as those of the sensor element 100 described above. The above description of FIGS. 1-6, is also applicable to FIG. 7, and is incorporated herein by reference. Thus, the above description may not be repeated here.

As illustrated in FIG. 7, a sensor element 300 may include a die 110, an active part 330 including a frame 332 surrounded by the die. A first trench 120 interposed between die 110 and the active part 330. At least one bridge 140 connecting the die 110 and the frame 332 to each other and having a second trench 150 formed therein.

The die 110 may be disposed in the vicinity of the frame 332 to surround the frame 332 while having a gap between the die 110 and the frame 332. The frame 332 may be accommodated in an internal space of the die. The first trench 120 may be provided between the die 110 and the frame 332 so that the die 110 and the frame 332 are spaced apart from each other. In an example, the first trench may have a through-hole shape.

As shown in FIG. 3, in an example, only the die 110 may be bonded and fixed to the substrate 500, and the active part 330 may not be fixed to the substrate, but may be elastically supported through the bridge 140. One end of the bridge 140 is fixed to the die 110.

A cavity may be formed in the frame 332.

For example, when the sensor element is applied to an acceleration sensor, the active part 330 may include a mass body 334 surrounded by the frame 332. A plurality of beams 338 connect the mass body and the frame to each other and elastically support the mass body. A plurality of sensing parts 336 are disposed on the beams. The plurality of sensing parts 336 sense deformation of the beams.

The mass body 334 may be disposed in the cavity formed in the frame 332, and may be positioned to be spaced apart from the frame. The mass body 334 may be connected to the frame by the plurality of beams 338.

Each beam 338 may have one end connected to the frame 332 and the other end connected to the mass body 334 to elastically support the mass body 334. Therefore, the mass body 334 may be supported in a state in which it is buoyed by the plurality of beams. The plurality of beams 338 may support the mass body 334 in four directions, and may be disposed symmetrically to each other in relation to the mass body.

The sensing part 336 may include a plurality of piezo-resistors (or piezoresistive elements), and may be formed on an upper surface of the beam 338.

For example, the mass body 334 may be displaced by a movement generated by external force, resistance values of the plurality of sensing parts 336 formed on the plurality of beams 338 may be changed through the displacement of the mass body 334, and acceleration may be sensed and measured through the change in the resistance values.

One end of the bridge 140 may be connected to the die 110 and the other end connected to the frame 332 to connect the die 110 and the frame 332 to each other.

In the sensor element 300, the bridge 140 may be formed in the manner of, for example, a cantilever spring to elastically support the frame 332.

Therefore, in a case in which stress is applied to the sensor element 300 by external force, the bridge 140 may alleviate the stress through bending, thereby blocking, to some degree, the external force from being directly introduced from the die 110 into the frame 332.

In addition, in the sensor element 300, the bridge 140 may have the second trench 150 formed at one side thereof to more elastically support the frame 332.

The second trench 150 may be formed together with the bridge 140 by etching the die 110. The second trench 150 may be formed in a thickness direction of the bridge. In detail, the second trench 150 may be shaped like a slit, which has a closed upper portion for connection and an open lower portion, i.e., the second trench may have a groove shape with a depth.

The second trench 150 may be formed in a lower portion of the bridge 140, and thus the sensing part 336 of the active part 330 and an electrode pad (not illustrated) placed on the die 110 may be electrically connected to each other through the bridge 140.

However, the second trench 150 is not limited to having the above-mentioned shape and disposition.

As described above, the second trench 150 may be formed in the bridge 140 to reduce a cross-sectional area of the bridge 140 connecting the active part 330 and the die 110 to each other, thereby more effectively blocking impact or external force from being transferred from the die 110 to the frame 332 of the active part 130.

When the impact or the external force is applied to the sensor element 300, the second trench 150 may become wide or narrow to block the transfer of the impact or the external force so that the active part 330 is not deformed due to external stress. Therefore, reliability of an operation of the sensor element may be maintained even in a case in which the impact or the external force is applied to the sensor element.

Meanwhile, although not illustrated, wiring patterns may be formed on surfaces of the die 110, the frame 332, and the bridge 140 connecting the die 110 and the frame 332 to each other. The wiring patterns may electrically connect the sensing parts 336 to electrical pads or the substrate 500.

FIG. 8 is a plan view illustrating a sensor element according to another example. Some of the components shown in FIG. 8 have been described with reference to FIGS. 1-7. The above description of FIGS. 1-7, is also applicable to FIG. 8, and is incorporated herein by reference. Thus, the above description may not be repeated here.

A sensor element 400 may correspond to a partial combination of the sensor element 200 and the sensor element 300.

As illustrated in FIG. 8, a sensor element 400 may include a die 410, an active part 430 including a frame 432 surrounded by the die. A first trench 420 is interposed between the die 410 and the active part 430. At least one elastic support part 440 connecting the die 410 and the frame 432 to each other. The elastic support part 440 includes an elastic part 442 and has a second trench 450 formed in the elastic part 442.

The die 410 may be disposed in the vicinity of the frame 432 to surround the frame 432 while having a gap between the die 410 and the frame 432. The frame 432 may be accommodated in an internal space of the die 410. The first trench 420 may be provided between the die 410 and the frame 432 so that the die 410 and the frame 432 are spaced apart from each other. In an example, the first trench may have a through-hole shape.

Similar to what is shown in FIG. 3, only the die 410 may be bonded and fixed to the substrate 500, and the active part 430 may not be fixed to the substrate, but may be elastically supported through the elastic support part 440. One end of the elastic support part 440 is fixed to the die.

A cavity may be formed in the frame 432.

For example, when the sensor element is applied to an acceleration sensor, the active part 430 may include a mass body 434 surrounded by the frame 432. A plurality of beams 438 connect the mass body 434 and the frame 432 and elastically supporting the mass body. A plurality of sensing parts 436 are disposed on the beams, and sense deformation of the beams.

The mass body 434 may be disposed in the cavity formed in the frame 432, and may be positioned to be spaced apart from the frame. The mass body 434 may be connected to the frame by the plurality of beams 438.

Each beam 438 may have one end connected to the frame 432 and the other end connected to the mass body 434 to elastically support the mass body 434. Therefore, the mass body 434 may be supported in a state in which it is buoyed by the plurality of beams. The plurality of beams 438 may support the mass body 434 in four directions, and may be disposed symmetrically to each other in relation to the mass body.

The sensing part 436 may include a plurality of piezo-resistors (or piezoresistive elements), and may be formed on an upper surface of the beam 438.

For example, the mass body 434 may be displaced by a movement generated by external force, resistance values of the plurality of sensing parts 436 formed on the plurality of beams 438 may be changed through the displacement of the mass body 434, and acceleration may be sensed and measured through the change in the resistance values.

One end of the elastic support part 440 may be connected to the die 410 and the other end connected to the frame 432 to connect the die 410 and the frame 432 to each other.

In the sensor element 400, the elastic support part 440 may include an elastic part 442 extended in parallel with an inner surface of the die 410 or an outer surface of the frame 432. The elastic part 442 may be positioned in the first trench 420. A pair of connection parts 444 may be formed from both ends of the elastic part 442 toward the inner surface of the die and the outer surface of the frame, respectively. Each of the connection parts 444 may be connected to the die 410 and the frame 432.

In an example, the elastic part 442 of the elastic support part 440 may have a leaf spring shape to elastically support the frame 432.

The connection parts 444 may be extended from both ends of the elastic part 442 toward the inner surface of the die 410 and the outer surface of the frame 432 in a direction approximately perpendicular to a length direction of the elastic part 442, and may have distal ends each connected to the die 410 and the frame 432.

Therefore, the die 410 and the frame 432 may be connected to both ends of the elastic part 442, respectively. Thus the elastic support part 440 may provide a buffering effect between the die 410 and the frame 432 through elastic force of the elastic part.

As illustrated in FIG. 8, four elastic support parts 440 may be disposed on four side surfaces of the frame 432. Therefore, the elastic support parts 440 may elastically support movement of the frame in four directions of the die 410.

When impact or external force is applied to the sensor element 400, the elastic support part 440 may alleviate the impact through the elastic force to significantly reduce direct introduction of the impact from the die 410 to the frame 432.

In addition, in the sensor element 400, at least one connection part 444 may have the second trench 450 formed at one side of the connection part 444 to more elastically support the frame 432.

The second trench 450 may be formed in a thickness direction of the connection part 444. The second trench 450 may be shaped like a slit, which has a closed upper portion for connection and an open lower portion, i.e., the second trench may have a groove shape with a depth.

The second trench 450 may be formed in a lower portion of the elastic support part 440, and thus the sensing part 436 of the active part 430 and an electrode pad (not illustrated) placed on the die 410 may be electrically connected to each other through the upper portion of the elastic support part 440.

The second trench 450 is not limited to having the above-mentioned shape and disposition, and other shape and disposition are considered to be well within the scope of the present disclosure. For example, second trench 450 may be formed in the elastic part 442.

As described above, the second trench 450 may be formed in the elastic support part 440. In an example, when the second trench 450 is formed in the connection part 444, it more effectively blocks the impact or the external force from being transferred from the die 410 to the frame 432 of the active part 430.

The active part 430 may be three-dimensionally and elastically moved by the elastic support part 440 having the configuration described above.

Therefore, in the sensor element 400, the second trench 450 may be formed in the elastic support part 440 to block the impact or the external force from being transferred from the die 410 to the active part 430, thereby solving a problem that a precision of measurement is reduced.

When the impact or the external force is applied to the sensor element 400, the second trench 450 may become wide or narrow to block the transfer of the impact or the external force so that the active part 430 is not deformed due to external stress. Therefore, reliability of an operation of the sensor element may be maintained even when the impact or the external force is applied to the sensor element.

Meanwhile, although not illustrated, wiring patterns may be formed on surfaces of the die 410, the frame 432, and the elastic support part 440 connecting the die 410 and the frame 432 to each other. The wiring patterns may electrically connect the sensing parts 436 to electrical pads or the substrate 500.

In an example, the sensor element configured as described above may be manufactured through micro electro mechanical system (MEMS) technology.

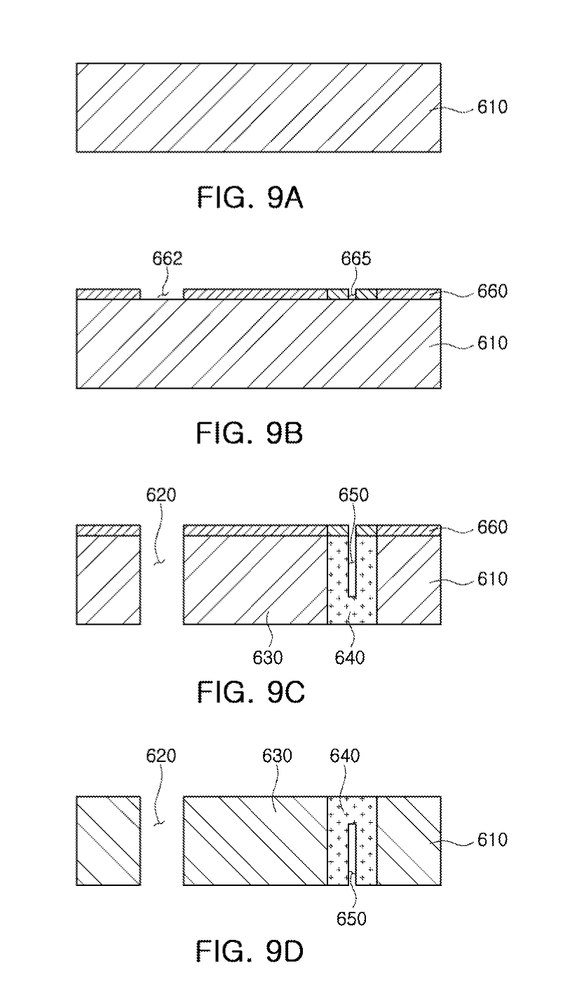

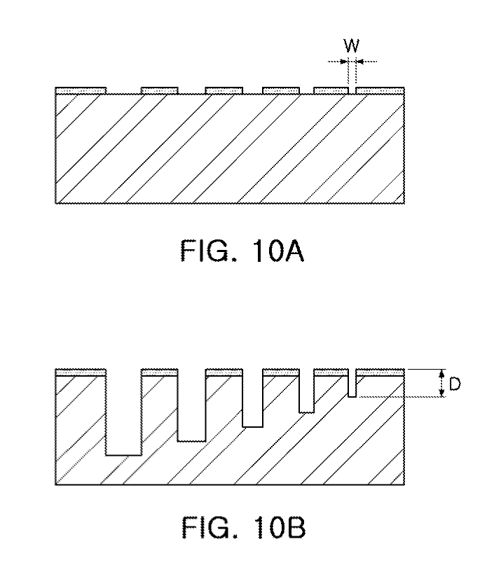

FIGS. 9A through 9D are diagrams illustrating examples of a method of manufacturing a sensor element. FIGS. 10A and 10B are diagrams illustrating examples of a microloading effect.

As illustrated in FIGS. 9A through 10B, the method of manufacturing a sensor element may include etching a die 610 using a mask 660 in which slit patterns 662 and 665 each corresponding to a first trench 620 and a second trench 650 are formed.

In an example, anisotropic etching may be performed on the die 610, and thus the first trench 620, a frame 632, and a bridge 640 or an elastic support part, and a second trench 650 formed on the bridge or the elastic support part of the sensor element may be implemented.

The first and second trenches may be formed one at a time or at the same time using deep reactive ion etching (DRIE) that may realize the manufacturing of a structure having a high aspect ratio. Other etching methods for forming a trench in a die are considered to be well within the scope of the present disclosure. DRIE may be a method of etching the die by colliding ions with the die at a fast speed.

In FIG. 9A, the die 610 may be prepared, and may be positioned so that an open surface of the second trench 650 is directed in an upward direction.

As illustrated in FIG. 9B, an etch mask 660 may be formed on the die 610.

The etch mask 660 may be deposited through processes, such as, for example, chemical vapor deposition (CVD), or an Al thin film. Materials, such as, for example, SiO₂ may be used as a material of the etch mask 660.

Exposure and development may be performed on the etch mask 660 through photolithography using a stepper, or the like, to form desired slit patterns.

As illustrated in FIG. 9C, the die 610 may be etched along the slit patterns using the etch mask 660 including the slit pattern 662 for forming the first trench 620 and the slit pattern 665 for forming the second trench 650. Here, the die 610 may be anisotropically etched through the DRIE.

The etch mask 660 may be removed after the die 610 is etched.

Referring to FIG. 9B, the slit pattern 665 for forming the second trench may be designed to have a width lesser than that of the slit pattern 662 for forming the first trench. The slit pattern 665 for forming the second trench may not be completely etched to the bottom due to a microloading effect illustrated in FIGS. 10A and 10B when the die is anisotropically etched through the DRIE.

According to the microloading effect, the narrower the width of a window of a mask, the lower the etch rate for the bottom of the trench. This is because a flow of ions is reduced depending on shade and shadow. It may be seen in FIG. 10B that a trench disposed at the rightmost portion, which is formed by a window having the narrowest width, is formed at the shallowest depth D.

The second trench 650 opened downward and having a narrow width may be formed as illustrated in FIG. 9D. The frame 632 may be connected at only a thickness to the die 610 through the bridge 640 or the elastic support having the second trench described above.

Therefore, a cross-sectional area of the bridge or the elastic support part connecting the active part and the die to each other may be reduced, thereby effectively blocking impact or external force from being transferred from the die to the frame.

When the sensor element is applied to a pressure sensor, a process of forming a cavity in an upper surface of the frame and a process of forming a membrane on the frame may be included.

When the sensor element according to the present disclosure is applied to an acceleration sensor, the cavity formed in the frame may be formed together with the first and second trenches when the first and second trenches are formed, and a process of forming a mass body and a plurality of beams in the frame may be included.

As described above, in the method of manufacturing a sensor element, since the first trench that penetrates through the die and the second trench that does not penetrate through the die and has a certain depth may be implemented one at a time or at the same time by adding only the slit patterns to the etch mask, an added mask or process may not be required.

Therefore, in the method of manufacturing a sensor element may be simplified and manufacturing cost may be reduced.

As set forth above, according to, the transfer of external stress to the active part may be significantly reduced, and the electrical connection from the active part to the electrode pad may be made, and thus a high performance sensor may be provided.

In addition, according to, the sensor element may be manufactured by a simple process without adding processes, and thus a manufacturing cost of the sensor element may be reduced.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A sensor element comprising:
a die;
an active part comprising a frame surrounded by the die;
a first trench disposed between the die and the active part; and
a bridge connecting the die and the frame and a second trench being formed in the bridge.

2. The sensor element of claim 1, wherein an end of the die is fixed to a substrate, and a space is formed between a lower end of the frame and the substrate.

3. The sensor element of claim 1, wherein the active part comprises:
a cavity formed in an upper surface of the frame;
a membrane formed on the upper surface of the frame to cover the cavity; and
at least one sensor disposed on the membrane.

4. The sensor element of claim 1, wherein the active part comprises:
a cavity formed in the frame;
a mass body disposed in the cavity and surrounded by the frame;
beams connecting the mass body and the frame to each other and elastically supporting the mass body; and
sensing parts disposed on the beams and being configured to sense a deformation of the beams.

5. The sensor element of claim 1, wherein the second trench is formed in a thickness direction of the bridge.

6. The sensor element of claim 2, wherein the end of the die is fixed to the substrate by an adhesion layer.

7. The sensor element of claim 3, wherein the sensor is disposed at a position where the membrane and the frame connect to each other.

8. The sensor element of claim 1, wherein the second trench is shaped as a groove with a depth of the groove being lesser than a thickness of the bridge.

9. The sensor element of claim 1, wherein the die protrudes below of the frame.

10. A sensor element comprising:
a die;
an active part comprising a frame surrounded by the die with a first trench disposed between the frame and the die; and
at least one elastic support part connecting the die and the frame, the elastic support part comprising an elastic part, and having a second trench formed in the elastic part.

11. The sensor element of claim 10, wherein an end of the die is fixed to a substrate, and
a space is formed between a lower end of the frame and the substrate.

12. The sensor element of claim 10, wherein the active part comprises:
a cavity formed in an upper surface of the frame;
a membrane formed on the upper surface of the frame to cover the cavity; and
at least one sensor disposed on the membrane.

13. The sensor element of claim 10, wherein the active part comprises:
a cavity formed in the frame;
a mass body disposed in the cavity and surrounded by the frame;
beams connecting the mass body and the frame to each other and elastically supporting the mass body; and
sensing parts disposed on the beams and being configured to sense deformation of the beams.

14. The sensor element of claim 10, wherein the elastic support part further comprises:
the elastic part being disposed parallel to an inner surface of the die or an outer surface of the frame and being positioned in the first trench; and
a first and a second connection part extending from two ends of the elastic part to connect the die and the frame, and the first connection part extending toward the inner surface of the die and the second connection part extending toward outer surface of the frame.

15. The sensor element of claim 14, wherein the second trench is formed in a thickness direction in the first or the second connection part.

16. The sensor element of claim 14, wherein the first and the second connection part extend from the elastic part in a direction approximately perpendicular to a length direction of the elastic.

17. A method of manufacturing a sensor element, the method comprising:
forming an etch mask on a die;
forming slit patterns for forming first and second trenches on the etch mask; and
anisotropically etching the die.

18. The method of claim 17, wherein a width of the slit pattern for forming the second trench is narrower than a width of the slit pattern for forming the first trench.

19. The method of claim 17, wherein the first and second trenches are formed at the same time through deep reactive ion etching (DRIE) during the anisotropical etching.
